(19) United States
(12) Patent Application Publication
(10) Pub. No.: US 2024/0363536 A1
(43) Pub. Date: Oct. 31, 2024

(54) SEMICONDUCTOR DEVICE

(71) Applicant: Samsung Electronics Co., Ltd., Suwon-si (KR)

(72) Inventors: Jinyoung PARK, Suwon-si (KR); Heonjong SHIN, Suwon-si (KR); Jaehyun KANG, Suwon-si (KR); Youngsoo SONG, Suwon-si (KR)

(73) Assignee: Samsung Electronics Co., Ltd., Suwon-si (KR)

(21) Appl. No.: 18/634,187

(22) Filed: Apr. 12, 2024

(30) Foreign Application Priority Data
Apr. 28, 2023 (KR) 10-2023-0056303

(51) Int. Cl. H01L 23/528; H01L 21/768; H01L 21/8238; H01L 23/48; H01L 27/092; H01L 29/06; H01L 29/417; H01L 29/423; H01L 29/66; H01L 29/775; H01L 29/786

(52) U.S. Cl. CPC H01L 23/5286; H01L 21/76898; H01L 21/823871; H01L 23/481; H01L 27/092; H01L 29/0673; H01L 29/41733; H01L 29/42392; H01L 29/66439; H01L 29/775; H01L 29/78696

(57) ABSTRACT

A semiconductor device may include a substrate including a first active region including first active patterns spaced apart by a first interval, a second active region including second active patterns spaced apart by a second interval, first and second source/drain regions on the first and second active regions, first and second contact structures connected to the first and second source/drain regions, first and second conductive through-structures connected to the first and second contact structures, a power delivery structure in contact with bottom surfaces of the first and second conductive through-structures, a frontside interconnection structure, and a backside interconnection structure. The first conductive through-structure may be connected to the first source/drain region through the first contact structure. The second conductive through-structure may be connected to the second source/drain region through the frontside interconnection structure. The second interval may be different than the first interval.

### CROSS-REFERENCE TO RELATED APPLICATION(S)

This application claims the benefit of priority to Korean Patent Application No. 10-2023-0056303 filed on Apr. 28, 2023 in the Korean Intellectual Property Office, the subject matter of which is hereby incorporated by reference in its entirety.

### BACKGROUND

The present disclosure relates to a semiconductor device.

As demand for high performance, high speed, and multifunctionalization of semiconductor devices increases, semiconductor devices may need to be increasingly integrated. In this regard, it may be necessary to implement patterns having a fine width or a fine separation distance. In addition, in order to improve a degree of integration, efforts have been made to develop semiconductor devices having a backside power delivery network (BSPDN) structure in which a power rail is disposed on a back surface of a wafer.

### SUMMARY

An aspect of the present disclosure provides a semiconductor device having an improved degree of integration and/or electrical properties.

According to an embodiment of the present disclosure, a semiconductor device may include a substrate including a first active region and a second active region, the first active region and the second active region extending in a first direction, the first active region including a plurality of first active patterns spaced apart from each other by a first interval, the second active region including a plurality of second active patterns spaced apart from each other by a second interval, the second interval being different from the first interval; an device isolation layer on the substrate, the device isolation layer surrounding the first active region and the second active region; a gate structure on the substrate, the gate structure extending in a second direction, the second direction intersecting the first direction; a first source/drain region on the first active region and a second source/drain region on the second active region, the first source/drain region and the second source/drain region on opposite sides of the gate structure, respectively; an interlayer insulating layer on the device isolation layer, the interlayer insulating layer covering the gate structure, the first source/drain region, and the second source/drain region; a first contact structure and a second contact structure passing through the interlayer insulating layer, the first contact structure and the second contact structure being connected to the first source/drain region and the second source/drain region, respectively; a first conductive through-structure and a second conductive through-structure electrically connected to the first contact structure and the second contact structure, respectively, the first conductive through-structure and the second conductive through-structure passing through the substrate and the interlayer insulating layer; a power delivery structure extending from a back surface of the substrate toward a front surface of the substrate, the power delivery structure in contact with a bottom surface of the first conductive through-structure and a bottom surface of the second conductive through-structure; a frontside interconnection structure on the front surface of the substrate, the frontside interconnection structure including frontside interconnection patterns; and a backside interconnection structure on the back surface of the substrate, the backside interconnection structure including backside interconnection patterns. The first conductive through-structure may be in contact with a lower portion of the first contact structure. The first conductive through-structure may be electrically connected to the first source/drain region through the first contact structure. The second conductive through-structure may be spaced apart from the second contact structure. The second conductive through-structure may be in contact with the frontside interconnection structure. The second conductive through-structure may be electrically connected to the second source/drain region through the frontside interconnection structure.

According to an embodiment of the present disclosure, a semiconductor device may include a substrate having a first region having a first pattern density and a second region having a second pattern density; first elements on the substrate in the first region; a first conductive through-structure passing through the substrate, the first conductive through-structure electrically connected to the first elements; second elements on the substrate in the second region; a second conductive through-structure passing through the substrate, the second conductive through-structure electrically connected to the second elements; a contact structure connected to at least one of each of the first elements in the first region or each of the second elements in the second region; a power delivery structure extending from a back surface of the substrate toward a front surface of the substrate, the power delivery structure in contact with a bottom surface of the first conductive through-structure and a bottom surface of the second conductive through-structure; a frontside interconnection structure electrically connected to at least one of the first elements or the second elements on the front surface of the substrate, the frontside interconnection structure including frontside interconnection patterns in contact with an upper surface of the contact structure; and a backside interconnection structure including backside interconnection patterns adjacent to the back surface of the substrate, the back surface of the substrate being opposite the front surface of the substrate. A level of an upper end of the first conductive through-structure is different from a level of an upper end of the second conductive through-structure, and at least one of the first conductive through-structure or the second conductive through-structure extends from the front surface of the substrate toward the back surface of the substrate and is spaced apart from the contact structure.

According to an embodiment of the present disclosure, a semiconductor device may include a substrate including a first active region, a second active region, and a third active region, the first active region, the second active region, and the third active region extending in a first direction, the first active region including a plurality of first active patterns spaced apart from each other by a first interval, the second active region including a plurality of second active patterns spaced apart from each other by a second interval, the second interval being different from the first interval, the third active region including a plurality of third active patterns spaced apart from each other by a third interval, the third interval being less than the second interval; an device isolation layer surrounding the first active region, the second active, and the third active region on the substrate; a gate structure extending in a second direction, the second direction intersecting the first direction; a first source/drain region on the first active region, a second source/drain region on the second active region, and a third source/drain region on the third active region, the first source/drain region, the second source/drain region, and the third drain region on opposite sides of the gate structure, respectively; an interlayer insulating layer on the device isolation layer, the interlayer insulating layer covering the gate structure, the first source/drain region, the second source/drain region, and the third source/drain region; a first contact structure and a second contact structure passing through the interlayer insulating layer, the first contact structure and the second contact structure being connected to the first source/drain region and the second source/drain region, respectively; a first conductive through-structure and a second conductive through-structure electrically connected to the first contact structure and the second contact structure, respectively, the first conductive through-structure and the second conductive through-structure passing through the substrate and the interlayer insulating layer; a third conductive through-structure extending from a back surface of the substrate toward a front surface of the substrate, the third conductive through-structure connected to the third source/drain region and below the third source/drain region; and power delivery structures extending from the back surface of the substrate toward the front surface of the substrate, the power delivery structures in contact with a bottom surface of the first conductive through-structure, a bottom surface of the second conductive through-structure, and a bottom surface of the third conductive through-structure, respectively. A level of an upper end of the second conductive through-structure may be higher than a level of an upper end of the first conductive through-structure. The level of the upper end of the first conductive through-structure may be higher than a level of an upper end of the third conductive through-structure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor device according to an example embodiment;

FIGS. 2A, 2B and 2C are schematic enlarged plan views of a semiconductor device according to an example embodiment;

FIGS. 3A, 3B and 3C are schematic cross-sectional views of a semiconductor device according to an example embodiment;

FIG. 4 are schematic cross-sectional views of a semiconductor device according to an example embodiment;

FIG. 5 are schematic cross-sectional views of a semiconductor device according to an example embodiment;

FIG. 6 are schematic cross-sectional views of a semiconductor device according to an example embodiment; and

FIGS. 7A, 7B, 7C, 7D, 7E and 7F are cross-sectional views illustrating sequential processes of a method of manufacturing a semiconductor device according to an example embodiment.

### DETAILED DESCRIPTION

Hereinafter, example embodiments of the present disclosure will be described with reference to the accompanying drawings. Hereinafter, the terms such as “top,” “upper portion,” “upper surface,” “above,” “bottom,” “lower portion,” “lower surface,” “below,” and “side surface” may be understood as being referred to, based on the drawings except for being denoted by reference numerals.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

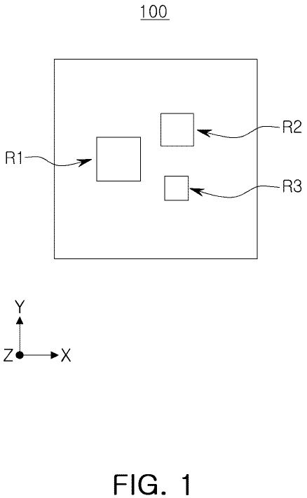

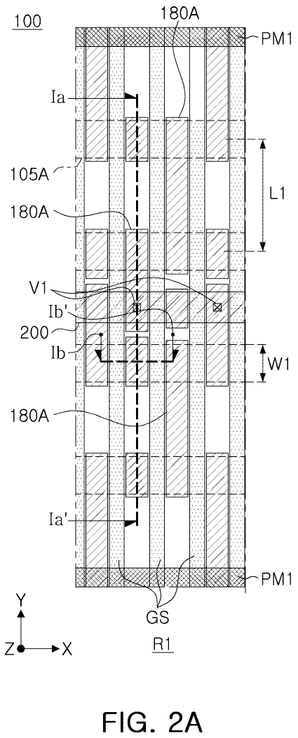

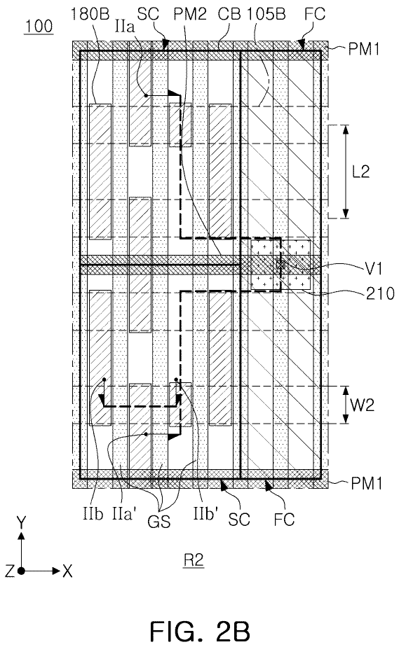

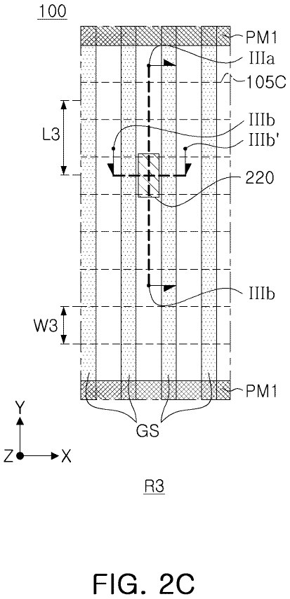

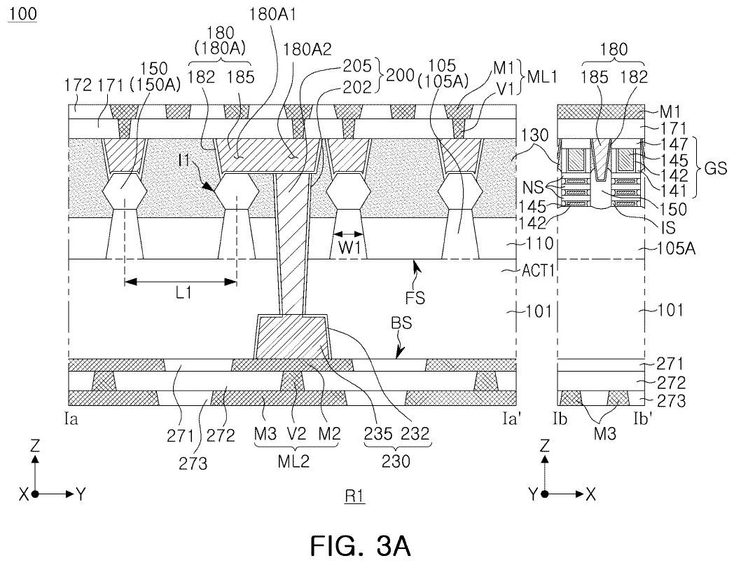

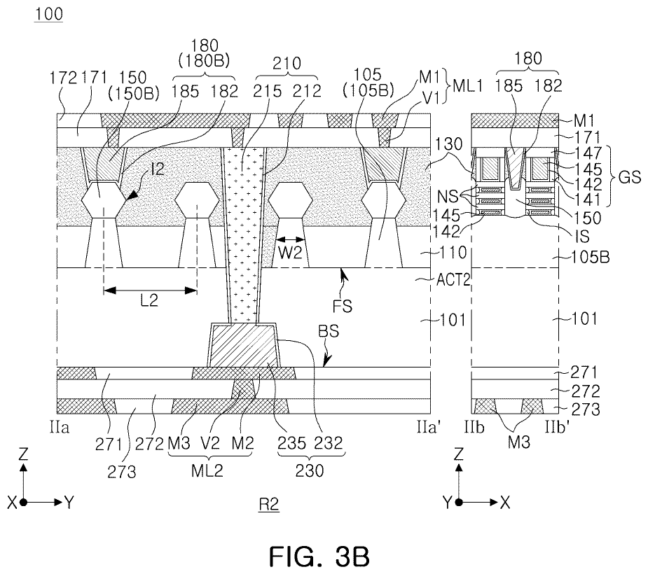

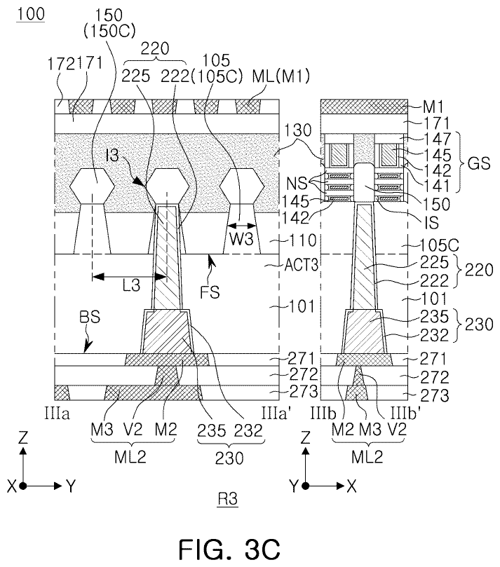

FIG. 1 is a schematic plan view of a semiconductor device according to an example embodiment. FIGS. 2A, 2B and 2C are schematic enlarged plan views of a semiconductor device according to an example embodiment. FIGS. 3A, 3B and 3C are schematic cross-sectional views of a semiconductor device according to an example embodiment.

FIGS. 2A, 2B and 2C are enlarged plan views of a first region R1, a second region R2, and a third region R3, arbitrary regions of FIG. 1, respectively. FIG. 3A illustrates cross-sections of the semiconductor device of FIG. 2A taken along lines Ia-Ia′ and Ib-Ib′. FIG. 3B illustrates cross-sections of the semiconductor device of FIG. 2B taken along lines IIa-IIa′ and IIb-IIb′. FIG. 3C illustrates cross-sections of the semiconductor device of FIG. 2C taken along lines IIIa-IIIa′ and IIIb-IIIb′. For ease of description, only some components of the semiconductor device are illustrated in FIGS. 2A, 2B and 2C.

Referring to FIGS. 1, 2A, 2B, 2C, 3A, 3B and 3C, a semiconductor device 100 may include a first region R1, a second region R2, and a third region R3, arbitrary regions. Each region may be classified based on pattern density (for example, cell density or the like), but the present disclosure is not limited thereto. Each region may include a plurality of semiconductor elements. The semiconductor element may be classified into a memory element and a logic element.

The memory element may form a volatile memory element or a nonvolatile memory element. For example, the volatile memory element may include a memory element such as a dynamic random access memory (DRAM), static RAM (SRAM), thyristor RAM (TRAM), zero capacitor RAM (ZRAM), or twin transistor RAM (TTRAM). In addition, the nonvolatile memory device may include a memory element, for example, a flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, nano floating gate memory, holographic memory, molecular electronics memory, or insulator resistance change memory.

The logic element may be implemented as, for example, a microprocessor, a graphic processor, a signal processor, a network processor, an audio codec, a video codec, an application processor, or a system on chip, but the present disclosure is not limited thereto.

The semiconductor device 100 may include a substrate 101, active regions ACT extending on the substrate 101 in a first direction X, an device isolation layer 110, a plurality of channel layers NS disposed on the active regions ACT to be vertically spaced apart from each other, a gate structure GS extending in a second direction Y, intersecting the first direction X, source/drain regions 150 disposed on the active regions ACT on opposite sides of the gate structure GS, an interlayer insulating layer 130 covering the gate structure GS and the source/drain regions 150, a contact structure 180 connected to the source/drain regions 150, a first conductive through-structure 200 and a second conductive through-structure 210 passing through the substrate 101 and the interlayer insulating layer 130, a power delivery structure 230 extending from a back surface BS of the substrate 101 toward a front surface FS of the substrate 101, a frontside interconnection structure ML1, and a backside interconnection structure ML2. The semiconductor device 100 may further include a third conductive through-structure 220. The source/drain regions 150 also may be referred to as source/drain structures.

The substrate 101 may have an upper surface extending in an X-direction and a Y-direction. The substrate 101 may include a semiconductor material, such as a Group IV semiconductor, a Group III-V compound semiconductor, or a Group II-VI compound semiconductor. For example, the Group IV semiconductor may include silicon, germanium, or silicon-germanium. The substrate 101 may be provided as a bulk wafer, an epitaxial layer, a silicon on insulator (SOI) layer, a semiconductor on insulator (SeOI) layer, or the like.

The substrate 101 may include active regions ACT disposed on an upper portion thereof. However, depending on the manner of description, the active regions ACT may be described as a separate component from the substrate 101. The substrate 101 may have a first region R1, a second region R2, and a third region R3. According to an example embodiment, the first region R1 may have a first pattern density, the second region R2 may have a second pattern density, and the third region R3 may have a third pattern density. For example, the first pattern density may be less than the second pattern density, and the second pattern density may be less than the third pattern density, but the present disclosure is not limited thereto. The first region R1, the second region R2, and the third region R3 may be classified depending on pattern density, but the present disclosure is not limited thereto.

In the second region R2 of FIG. 2B, the semiconductor device 100 according to the present example embodiments may include standard cells SC and pillar cells FC provided as a dummy region. The standard cells SC may extend to respectively form rows in a first direction (for example, X-direction), and may be arranged in a plurality of rows in a second direction (for example, Y-direction), perpendicular to the first direction. The pillar cells FC may provide a dummy region.

The standard cells SC arranged in respective rows may have a uniform cell height defined in the second horizontal direction. Standard cells SC positioned in the same row have the same cell height, but standard cells SC positioned in some rows may have cell heights different from those of standard cells SC positioned in other rows. The standard cells SC may have different widths in the first direction (for example, X-direction) even when positioned in the same row.

Herein, the term “height” (for example, “cell height”) used in relation to a standard cell may refer to a length or a distance in the second direction (for example, Y-direction) in plan view.

First and second power lines PM1 and PM2, supplying power to the standard cells SC, may respectively extend in the first direction (X-direction) along boundaries of the standard cells SC. The first and second power lines PM1 and PM2 may be arranged to be spaced apart from each other in the second horizontal direction (Y-direction). The first and second power lines PM1 and PM2 may supply different potentials to the standard cells SC positioned therebetween, respectively. Among the first and second power lines PM1 and PM2, a power line disposed at a boundary between standard cells SC in two adjacent rows may be a power line shared by the adjacent standard cells SC. At least one of the first and second power lines PM1 and PM2 may be arranged to cross at least one of the standard cells SC and filler cells FC. Each of the standard cells SC may have a P-type device region and an N-type device region arranged in the second horizontal direction (for example, Y-direction). The P-type device region may be a region in which a PMOS transistor is disposed, and the N-type device region may be a region in which an NMOS transistor is disposed. Although the active regions ACT are illustrated as having the same height, the heights of the active regions ACT may be differently adjusted for each of the standard cells SC in some example embodiments.

In the present example embodiment, the standard cells SC and the filler cells FC are described in connection with the second region R2, but the present disclosure is not limited thereto, and the description of the standard cells SC and the filler cells FC may be applied to the first region R1 of FIG. 2A and the third region R3 of FIG. 2C in the same manner.

The active regions ACT may be disposed to extend in the first direction, for example, the X-direction. The active regions ACT may be defined to have a desired and/or alternatively predetermined depth from an upper surface of a portion of the substrate 101. The active regions ACT may be formed of a portion of the substrate 101 or may include an epitaxial layer grown from the substrate 101. The active regions ACT1 include a first active region ACT1 disposed in the first region R1, a second active region ACT2 disposed in the second region R2, and a third active region ACT3 disposed in the third region R3. Each of the active regions ACT may include upwardly protruding active fins, for example, a plurality of active patterns 105. For example, the first active region ACT1 may include a plurality of first active patterns 105A spaced apart from each other by a first interval L1, the second active region ACT2 may include a plurality of second active patterns 105B spaced apart from each other by a second interval L2, different from the first interval L1, and the third active region ACT3 may include a plurality of third active patterns 105C spaced apart from each other by a third interval L3, different from the first and second intervals L1 and L2. The first interval L1 may be greater than the second interval L2, and the second interval L2 may be greater than the third interval L3, but the present disclosure is not limited thereto. According to an example embodiment, the plurality of first active patterns 105A, the plurality of second active patterns 105B, and the plurality of third active patterns 105C may respectively have widths W1, W2 and W3 that are substantially the same, but the present disclosure is not limited thereto. According to another example embodiment, each of the plurality of first active patterns 105A may have a first width W1, each of the plurality of second active patterns 105B may have a second width W2, different from the first width W1, and each of the plurality of third active patterns 105C may have a third width W3. For example, the first width W1 may be greater than the second width W2, and the second width W2 may be greater than the third width W3, but the present disclosure is not limited thereto.

The active regions ACT may form, together with the plurality of channel layers NS, an active structure in which a channel region of a transistor is formed. Each of the active regions ACT may include an impurity region. The impurity region may form at least a portion of a well region of a transistor. An device isolation layer 110 may be positioned between a plurality of active patterns 105 adjacent to each other in the Y-direction. Upper surfaces of the plurality of active patterns 105 may be positioned on a level higher than that of an upper surface of the device isolation layer 110. The plurality of active patterns 105 may be partially recessed on opposite sides of the gate structures GS, and the source/drain regions 150 may be disposed on the recessed regions, respectively.

The device isolation layer 110 may fill a space between the active regions ACT, and may define the active regions ACT including the active regions ACT on the substrate 101. The device isolation layer 110 may be formed using, for example, a shallow trench isolation (STI) process. The device isolation layer 110 may expose upper surfaces of the active patterns 105 or partially expose the upper surfaces of the active patterns 105. The device isolation layer 110 may be formed of an insulating material. The device isolation layer 110 may include, for example, oxide, nitride, or a combination thereof.

The plurality of channel layers NS may be disposed on the active patterns 105 to be vertically spaced apart from each other. The semiconductor device 100 may further include internal spacers IS disposed to be parallel to a gate electrode 145 between the plurality of channel layers NS. The semiconductor device 100 may include transistors having a gate-all-around structure in which the gate electrode 145 is disposed between the active patterns 105 and the channel layers NS and between the plurality of channel layers NS having a nano-sheet shape. For example, the semiconductor device 100 may include the plurality of channel layers NS, the source/drain regions 150, and transistors having a multi bridge channel FET (MBCFET™) structure, transistors formed by the gate electrode 145.

The plurality of channel layers NS may be disposed as two or more channel layers spaced apart from each other in a direction, perpendicular to upper surfaces of the active patterns 105, for example, in a third direction Z. The channel layers NS may be spaced apart from the upper surfaces of the active patterns 105 while being connected to the source/drain regions 150. The channel layers NS may have a width the same as or similar to that of each of the active patterns 105 in the second direction Y, and may have a width the same as or similar to that of each of the gate structure GS in the first direction X. However, as in the present example embodiment, when the internal spacers IS are used, the channel layers NS may have a width less than that of each of side surfaces of lower portions of the gate structure GS.

The plurality of channel layers NS may be formed of a semiconductor material, and may include, for example, at least one of silicon (Si), silicon germanium (SiGe), and germanium (Ge). The channel layers NS may be formed of, for example, a material the same as that of the substrate 101. In example embodiments, the number and shape of the channel layers NS, forming a single channel structure, may be changed in various manners. For example, in some example embodiments, a channel layer may be further positioned in a region in which the active patterns 105 are in contact with the gate electrode 145.

The gate structure GS may be disposed to extend from upper portions of the active patterns 105 and the plurality of channel layers NS to intersect the active patterns 105 and the plurality of channel layers NS. Channel regions of transistors may be formed in the active patterns 105 and the plurality of channel layers NS intersecting the gate structure GS. In the present example embodiment, a gate dielectric layer 142 may be disposed not only between the active pattern 105 and the gate electrode 145 but also between the plurality of channel layers NS and the gate electrode 145. The gate electrode 145 may be disposed on the upper portions of the active patterns 105 to fill a space between the plurality of channel layers NS and to extend to the upper portions of the plurality of channel layers NS. The gate electrode 145 may be spaced apart from the plurality of channel layers NS by the gate dielectric layer 142.

The internal spacers IS may be disposed to be parallel to the gate electrode 145 between the plurality of channel layers NS. The gate electrode 145 may be spaced apart from the source/drain regions 150 by the internal spacers IS to be electrically isolated from the source/drain regions 150. Side surfaces of the internal spacers IS, opposing the gate electrode 145, may be flat or may have a rounded shape, curved inwardly toward the gate electrode 145. The internal spacers IS may be formed of oxide, nitride, and oxynitride, and particularly may be formed of a low-K film. In some other example embodiments, the semiconductor device 100 is implemented to include a vertical field effect transistor (FET) in which an active region extending to be perpendicular to an upper surface of the substrate 101 and a gate structure surrounding the active region are disposed.

The gate structure GS may have a linear shape extending in the second direction Y. The gate structure GS may be disposed in one region of the active pattern 105. The gate structure GS may include gate spacers 141, a gate dielectric layer 142 and a gate electrode 145 sequentially disposed between the gate spacers 141, and a gate capping layer 147. For example, the gate spacers 141 may include an insulating material such as SiOCN, SiON, SiCN, or SiN. The gate dielectric layer 142 may be formed of, for example, a silicon oxide film, a high-K film, or a combination thereof. The high-K film may include a material having a dielectric constant higher than that of the silicon oxide film. For example, the high-K film may include a material selected from among hafnium oxide, hafnium oxynitride, hafnium silicon oxide, lanthanum oxide, lanthanum aluminum oxide, and combinations thereof, but the present disclosure is not limited thereto. The gate electrode 145 may include a conductive material, for example, a metal nitride such as titanium nitride (TiN), tantalum nitride (TaN), or tungsten nitride (WN), and/or a metal material such as aluminum (Al), tungsten (W) or molybdenum (Mo) or a semiconductor material such as doped polysilicon. In some example embodiments, the gate electrode 145 may be a multilayer including two or more films. In addition, the gate capping layer 147 may include, for example, silicon nitride, silicon oxynitride, silicon carbonitride, or silicon oxycarbonitride. According to an example embodiment, the gate structures GS, disposed on boundaries between the standard cells SC and the pillar cells FC, may be dummy gate structures GS.

The source/drain region 150 may be disposed on the active region ACT positioned on opposite sides of the gate structure GS. According to an example embodiment, the source/drain region 150 may include a first source/drain region 150A disposed on the first active region ACT1, a second source/drain region 150B disposed on the second active region ACT2, and a third source/drain region 150C disposed on the third active region ACT3.

The source/drain regions 150 may be respectively connected to opposite ends of the plurality of channel layers NS in the first direction (for example, X-direction). The gate electrode 145 may extend in the second direction (for example, Y-direction) to intersect the active region ACT while surrounding the plurality of channel layers NS. The gate electrode 145 may be interposed not only in a space between the gate spacers 141 but also a space between the plurality of channel layers NS.

The internal spacers IS provided between each of the source/drain regions 150 and the gate electrode 145 may be included. The internal spacers IS may be provided on opposite sides of the gate electrode 145 interposed between the plurality of channel layers NS in the first direction (for example, X-direction). The plurality of channel layers NS may be respectively connected to the source/drain regions 150 on opposite sides thereof, and the gate electrodes 145 interposed between the plurality of channel layers NS may be electrically insulated from the source/drain regions 150 at the opposite sides thereof by the internal spacers IS. The gate dielectric layer 142 may be interposed between the gate electrode 145 and each of the channel layers NS, and may also extend between the gate electrode 145 and the internal spacers IS.

The source/drain region 150 may include an epitaxial pattern selective epitaxially grown using, as a seed, a recessed surface of the active pattern 105 (including side surfaces of the plurality of channel layers NS) on opposite sides of the gate structure GS. The source/drain region 150 may also be referred to as a raised source/drain (RSD). For example, the source/drain regions 150 may be Si, SiGe, or Ge, and may have one of N-type conductivity or P-type conductivity. When a P-type source/drain region 150 is formed, the P-type source/drain region 150 may be re-grown with SiGe, and may be doped with P-type impurities, for example, boron (B), indium (In), gallium (Ga), boron trifluoride (BF₃), or the like. When an N-type source/drain region 150 is formed of silicon (Si), the N-type source/drain region 150 may be doped with N-type impurities, for example, phosphorus (P), nitrogen (N), arsenic (As), antimony (Sb), or the like. The source/drain region 150 may have different shapes along a crystallographically stable surface during a growth process. For example, as illustrated in FIGS. 3A, 3B and 3C, the source/drain region 150 may have a cross-section having a pentagonal shape (when the source/drain region 150 is a P-type source/drain region), but may alternatively have a cross-section having a hexagonal shape or a polygonal shape with a gentle angle (when the source/drain region 150 is an N-type source/drain region).

The interlayer insulating layer 130 may be disposed around the gate structure GS while partially covering the source/drain regions 150. The interlayer insulating layer 130 may be disposed on the device isolation layer 110, and may cover the gate structure GS and the first to third source/drain regions 150A, 150B, and 150C. For example, the interlayer insulating layer 130 may be formed of flowable oxide (FOX), Tonen silazene (TOSZ), undoped silica glass (USG), borosilica glass (BSG), phosphosilica glass (PSG), borophosphosilica glass (BPSG), high density plasma (HDP) oxide, plasma enhanced oxide (PEOX), flowable CVD (FCVD) oxide, or combinations thereof.

The contact structure 180 may pass through the interlayer insulating layer 130, and may be connected to the source/drain regions 150 and first to third conductive through-structures 200, 210, and 220. The contact structure may be connected to at least one of each of first elements I1, each of second elements I2, or each of third elements I3 in at least one of the first region R1 to the third region R3. The contact structure 180 may include first to third contact structures 180A, 180B, and 180C respectively connected to the first to third source/drain regions 150A, 150B, and 150C.

The first and second contact structures 180A and 180B may interconnect the first and second source/drain regions 150A and 150B and the frontside interconnection structure ML1. The contact structure 180 is not illustrated as being on the third source/drain region 150C, but the present disclosure is not limited thereto. A gate contact structure may be further disposed on the gate electrode 145 in a region not illustrated. The first contact structure 180A may be configured to connect the first source/drain region 150A and the first conductive through-structure 200 to each other. Specifically, the first contact structure 180A according to the present example embodiment may include a first contact portion 180A1 connected to the first source/drain region 150A, and a second contact portion 180A2 connected to the first conductive through-structure 200. The second contact portion 180A2 may extend from the first contact portion 180A1 in the second direction (for example, Y-direction) to be easily connected to the first conductive through-structure 200.

The contact structure 180 may include a metal silicide layer positioned at a lower end thereof, and may further include a barrier layer 182 disposed on the metal silicide layer and sidewalls, and a plug conductive layer 185. According to an example embodiment, the barrier layer 182 may be disposed along a portion of a sidewall and a lower surface of the contact structure 180. The barrier layer 182 may include, for example, a metal nitride such as titanium nitride (TiN), tantalum nitride (TaN), or tungsten nitride (WN). The plug conductive layer 185 may include, for example, a metal material such as aluminum (Al), tungsten (W), or molybdenum (Mo). In example embodiments, the number and arrangement of conductive layers, forming the contact structure 180, may be changed in various manners.

The first to third conductive through-structures 200, 210, and 220 may be buried in the interlayer insulating layer 130 and the device isolation layer 110 to be electrically connected to the first to third source/drain regions 150A, 150B, and 150C. The first to third conductive through-structures 200, 210, and 220 may serve as an electrical path for receiving power supply voltage from a backside interconnection structure ML2 and supplying the power supply voltage to the first to third elements I1, I2, and I3. According to an example embodiment, in the first region R1 having a first pattern density, the first conductive through-structure 200 may serve as an electrical path for receiving power supply voltage from the backside interconnection structure ML2 and supplying the power supply voltage to the first elements I1 through the frontside interconnection structure ML1 and the first contact structure 180A. In the second region R2 having a second pattern density higher than the first pattern density, the second conductive through-structure 210 may serve as an electrical path for receiving power supply voltage from the backside interconnection structure ML2 and supplying the power supply voltage to the second elements I2 through the frontside interconnection structure ML1 and a second contact structure 180B. In the third region R3 having a third pattern density higher than the second pattern density, the third conductive through-structure 220 may serve as an electrical path for receiving power supply voltage from the backside interconnection structure ML2 and supplying the power supply voltage to the third elements I3.

The first conductive through-structure 200 may be disposed to electrically connect the contact structure 180 and the backside interconnection structure ML2 to each other. At least a portion of the first conductive through-structure 200 may overlap the contact structure 180 in the Y-direction and a Z-direction, perpendicular to the upper surface of the substrate 101.

Each of the first and second conductive through-structures 200 and 210 may have an inclined side surface such that a width thereof decreases toward the substrate 101 due to an aspect ratio thereof, and the third conductive through-structure 220 may have an inclined side surface such that a width thereof increases in a direction away from the substrate 101, but the present disclosure is not limited thereto. Opposite side surfaces of the first to third conductive through-structures 200, 210, and 220 in the Y-direction may have regions having different inclinations. The first to third conductive through-structures 200, 210, and 220 may respectively include first to third contact plugs 205, 215, and 225, and first to third insulating liners 202, 212, and 222 respectively surrounding side surfaces of the first to third contact plugs 205, 215, and 225.

At least one of the first to third contact plugs 205, 215, and 225 may include, for example, Cu, Co, Mo, Ru, W, or alloys thereof. The first to third insulating liners 202, 212, and 222 may include, for example, oxide, nitride, oxynitride, SiO₂, SiN, SiCN, SiC, SiCOH, SiON, Al₂O₃, AlN, or combinations thereof.

Although not illustrated, at least one of the first through third conductive through-structures 200, 210, and 220 may include a conductive barrier. The conductive barrier may include, for example, Ta, TaN, Mn, MnN, WN, Ti, TiN, or combinations thereof, and the conductive barrier may cover a side surface of at least one of the first to third contact plugs 205, 215, and 225. For example, the conductive barrier may be disposed between the first to third insulating liners 202, 212, and 222 and the first to third contact plugs 205, 215, and 225.

The first and second conductive through-structures 200 and 210 may pass through at least a portion of the device isolation layer 110, and the third conductive through-structure 220 may pass through the third active patterns 105C. According to an example embodiment, the first and second conductive through-structures 200 and 210 may pass through at least a portion of the interlayer insulating layer 130 and the device isolation layer 110 and extend in the third direction Z. The third conductive through-structure 220 may pass through at least a portion of the substrate 101 and the third active patterns 105C and extend in the third direction Z.

The first and second conductive through-structures 200 and 210 may extend from the front surface FS of the substrate 101 toward the back surface BS of the substrate 101, and the third conductive through-structure 220 may extend from the front surface FS of the substrate 101 toward the back surface BS of the substrate 101. Each of the first and second conductive through-structures 200 and 210 may have a width increasing from the back surface BS of the substrate 101 toward the front surface FS of the substrate 101, and the third conductive through-structure 220 may have a width decreasing from the back surface BS of the substrate 101 toward the front surface FS of the substrate 101.

The width of the first conductive through-structure 200 in the Y-direction may be greater than the width of the second conductive through-structure 210 in the Y-direction, but the present disclosure is not limited thereto. According to another example embodiment, in the first region R1 to the third region R3, the width of each of the first through third conductive through-structures 200, 210, and 220 in the Y-direction may vary depending on a pattern density.

The first conductive through-structure 200 may be spaced apart from the first elements I1, but may be electrically connected to the first elements I1 through the first contact structure 180A. According to an example embodiment, the first conductive through-structure 200 may be in contact with a lower portion of the first contact structure 180A, and may be electrically connected to the first source/drain region 150A through the first contact structure 180A. The first conductive through-structure 200 may be in contact with the lower portion of the first contact structure 180A through an upper surface thereof. The first conductive through-structure 200 may extend in the first direction X, and may be in contact with a lower surface of the first contact structure 180A. According to an example embodiment, a level of an upper end of the first conductive through-structure 200 may be lower than a level of an upper end of the first contact structure 180A. The level of the upper end of the first conductive through-structure 200 may be different from a level of an upper end of the second conductive through-structure 210. According to an example embodiment, the level of the upper end of the first conductive through-structure 200 may be lower than the level of the upper end of the second conductive through-structure 210, and may be higher than a level of an upper end of the third conductive through-structure 220.

The second conductive through-structure 210 may be spaced apart from the second contact structure 180B, and may be in contact with a lower portion of the frontside interconnection structure ML1. The second conductive through-structure 210 may be spaced apart from the second elements I2, but may be electrically connected to the second elements I2 through the frontside interconnection structure ML1. The level of the upper end of the second conductive through-structure 210 may be substantially the same as a level of an upper end of the second contact structure 180B. According to an example embodiment, an upper surface or upper end of the second conductive through-structure 210 may be positioned on a level higher than that of an upper surface or upper level of each of the second source/drain regions 150B.

The third conductive through-structure 220 may pass through the substrate 101 and the third active patterns 105C, and may be in contact with the third elements I3. According to an example embodiment, the third conductive through-structure 220 may be connected to the third source/drain region 150C below the third source/drain region 150C. Although not illustrated, the third conductive through-structure 220 may be disposed to be spaced apart from the contact structure 180 corresponding to the first and second contact structures 180A and 180B.

The power delivery structure 230 may extend from the back surface BS of the substrate 101 toward the front surface FS of the substrate 101 to be in contact with a bottom surface of each of the first to third conductive through-structures 200, 210, and 220. The power delivery structure 230 may be electrically connected to the first to third conductive through-structures 200, 210, and 220 within the substrate 101. According to an example embodiment, the power delivery structure 230 may have a rail shape extending in the first direction X. The power delivery structure 230 may be disposed below the conductive through-structure 200, and may be connected to lower ends or lower surfaces of the first to third conductive through-structures 200, 210, and 220. The power delivery structure 230 may form a backside power delivery network (BSPDN) applying power or ground voltage, and may also be referred to as a buried power rail. For example, the power delivery structure 230 may be a buried interconnection line extending in one direction, for example, in the X-direction, below the first to third conductive through-structures 200, 210, and 220, but a shape of the power delivery structure 230 is not limited thereto. The power delivery structure 230 may be further connected to first to third conductive through-structures 200, 210, and 220 not illustrated in a region not illustrated.

The power delivery structure 230 may have an inclined side surface such that a width thereof decreases toward an upper portion thereof. That is, the power delivery structure 230 may have a trapezoidal shape. The power delivery structure 230 may include a fourth contact plug 235 and a fourth insulating liner 232 surrounding a side surface of the fourth contact plug 235.

At least one of the fourth contact plugs 235 may include, for example, Cu, Co, Mo, Ru, W, or alloys thereof. In the present example embodiment, the first to third contact plugs 205, 215, and 225 and the fourth contact plug 235 may include different conductive materials. In some example embodiments, the first to third contact plugs 205, 215, and 225 may include Mo. The fourth contact plug 235 may include Cu or W.

The fourth insulating liner 232 may cover at least a portion of an upper surface and a side surface of the fourth contact plug 235. At least one of the fourth insulative liners 232 may include, for example, oxide, nitride, oxynitride, SiO₂, SiN, SiCN, SiC, SiCOH, SiON, Al₂O₃, AlN, or combinations thereof.

Although not illustrated, the power delivery structure 230 may include a conductive barrier. The conductive barrier may include, for example, Ta, TaN, Mn, MnN, WN, Ti, TiN, or combinations thereof, and may cover the side surface of the fourth contact plug 235. For example, the conductive barrier may be disposed between the fourth insulating liner 232 and the fourth contact plug 235.

The frontside interconnection structure ML1 may be disposed on the front surface FS of the substrate 101. The frontside interconnection structure ML1 may include a plurality of first dielectric layers 171 and 172 and frontside interconnection patterns M1 and V1. The plurality of first dielectric layers 171 and 172 may include first dielectric layers 171 and 172 disposed on the interlayer insulating layer 130. The frontside interconnection patterns M1 and V1 may include a plurality of frontside interconnection lines M1 and a plurality of frontside interconnection vias V1. A plurality of frontside interconnection lines M1 may be formed in the first upper dielectric layer 172, and a plurality of frontside interconnection vias V1 may be formed in the first lower dielectric layer 171. The plurality of frontside interconnection lines M1 may pass through the first upper dielectric layer 172. The plurality of frontside interconnection vias V1 may pass through the first lower dielectric layer 171. Each of the plurality of frontside interconnection vias V1 may have an inclined side surface having a width decreasing in a direction toward the substrate 101, but the present disclosure is not limited thereto. The frontside interconnection structure ML1 may be electrically connected to at least one of the first elements I1 and the second elements I2.

The first dielectric layers 171 and 172 may include, for example, at least one of oxide, nitride, and oxynitride, and may include silicon oxide, silicon oxynitride, SiOC, SiCOH, or combinations thereof. For example, the plurality of frontside interconnection lines M1 and the plurality of frontside interconnection vias V1 may include copper or a copper-containing alloy. In some example embodiments, the plurality of frontside interconnection lines M1 and the plurality of frontside interconnection vias V1 may be formed together using a dual-damascene process. In some example embodiments, the number of frontside interconnection patterns M1 and V1 may be changed in various manners.

The backside interconnection structure ML2 may be disposed on the back surface BS of the substrate 101, and may be electrically connected to the conductive through-structure 200. The backside interconnection structure ML2 may include backside interconnection patterns M2, V2, and M3. In a similar manner to the frontside interconnection structure ML1, the backside interconnection structure ML2 may include a plurality of second dielectric layers 271, 272, and 273, a plurality of backside interconnection lines M2 and M3, and a plurality of backside interconnection vias V2. The backside interconnection patterns M2, V2, and M3 may include the plurality of backside interconnection lines M2 and M3 and the plurality of backside interconnection vias V2. The backside interconnection structure ML2 according to the present example embodiment may be understood as an interconnection portion replacing a portion of the frontside interconnection structure ML1, a BEOL. In the present example embodiment, the backside interconnection structure ML2 may be an interconnection portion for power delivery, and the frontside interconnection structure ML1 may be provided as an interconnection portion for signal delivery.

Thus, in the present example embodiment, a signal network may be connected from the frontside interconnection structure ML1 to an element region (for example, the source/drain region 150 and the gate electrode 145), positioned on the front surface FS of the substrate 101, through the contact structure 180, and a power delivery network may pass through the substrate 101, and may be connected from the backside interconnection structure ML2 positioned on a lower surface of the substrate 101 to an element region (for example, the source/drain region 150 and the first to third elements I1, I2, and I3).

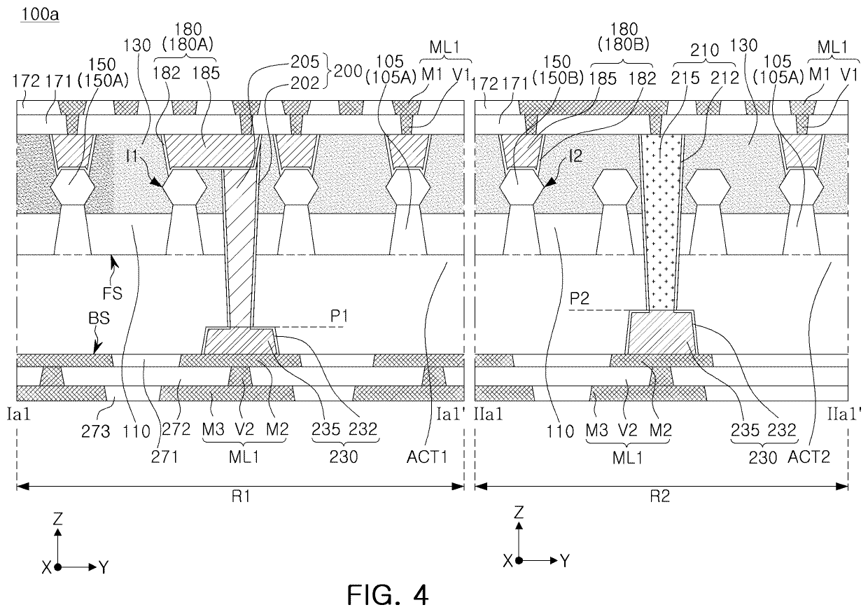

FIG. 4 are schematic cross-sectional views of a semiconductor device according to an example embodiment. FIG. 4 illustrates a cross-sectional view corresponding to a cross-section taken along IIa-IIa′ of FIG. 3B and a cross-sectional view corresponding to a cross-section taken along IIIa-IIIa′ of FIG. 3C as a cross-sectional view taken along IIa1-IIa1′ and a cross-sectional view taken along IIIa1-IIIa1′, respectively. In the following description, contents overlapping those described above will be omitted.

Unlike the semiconductor device 100 of FIGS. 1, 2A, 2B, 2C, 3A, 3B and 3C, power supply voltage may be supplied to a semiconductor device 100a by a first conductive through-structure 200 and a second conductive through-structure 210 excluding a third conductive through-structure 220 on a substrate 101.

In the semiconductor device 100a, the first conductive through-structure 200 and the second conductive through-structure 210 may be disposed in each region of the substrate 101. According to an example embodiment, power may be supplied to first elements I1 and the second elements I2 in different manners by the first conductive through-structure 200 and the second conductive through-structure 210. For example, in a first region R1 having a first pattern density, the first conductive through-structure 200 may serve as an electrical path for receiving power supply voltage from a backside interconnection structure ML2 and supplying the power supply voltage to the first elements I1 through a frontside interconnection structure ML1 and a first contact structure 180A. In a second region R2 having a second pattern density higher than the first pattern density, the second conductive through-structure 210 may serve as an electrical path for receiving power supply voltage from the backside interconnection structure ML2 and supplying the power supply voltage to the second elements I2 through the frontside interconnection structure ML1 and a second contact structure 180B. The second conductive through-structure 210 may be connected to a power delivery structure 230 extending from a back surface BS of the substrate 101. According to an example embodiment, a first level P1 of a contact surface between the first conductive through-structure 200 and the power delivery structure 230 may be lower than a second level P2 of a contact surface between the second conductive through-structure 210 and the power delivery structure 230, but the present disclosure is not limited thereto. According to an example embodiment, the first conductive through-structure 200 may be in contact with at least a portion of a side surface of the first contact structure 180A.

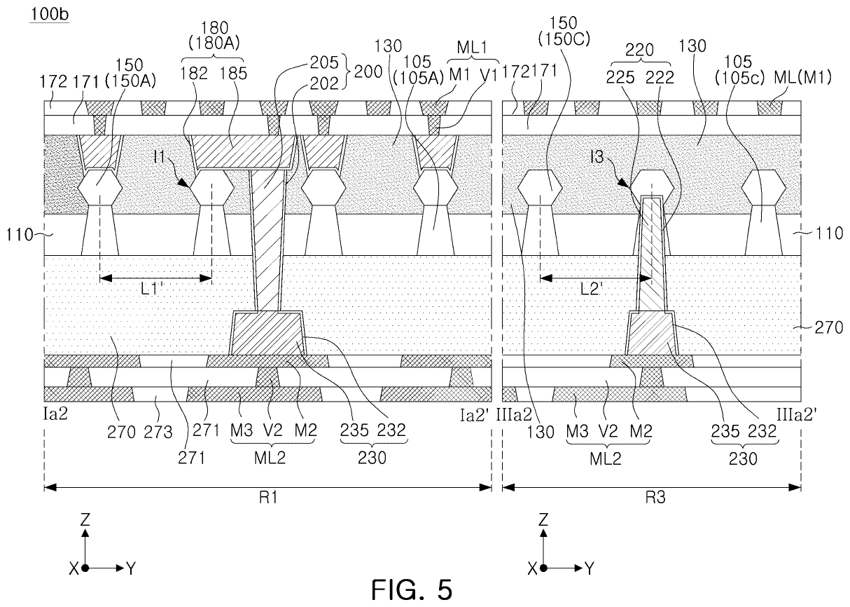

FIG. 5 are schematic cross-sectional views of a semiconductor device according to an example embodiment. FIG. 5 illustrates a cross-sectional view corresponding to a cross-section taken along IIa-IIa′ of FIG. 3B and a cross-sectional view corresponding to a cross-section taken along IIIa-IIIa′ of FIG. 3C as a cross-sectional view taken along IIa2-IIa2′ and a cross-sectional view taken along IIIa2-IIIa2′, respectively. In the following description, contents overlapping those described above will be omitted.

Unlike the semiconductor device 100 of FIGS. 1, 2A, 2B, 2C, 3A, 3B and 3C, a semiconductor device 100b may include a lower interlayer insulating layer 270. In addition, power supply voltage may be supplied by a first conductive through-structure 200 and a third conductive through-structure 220 excluding a second conductive through-structure 210.

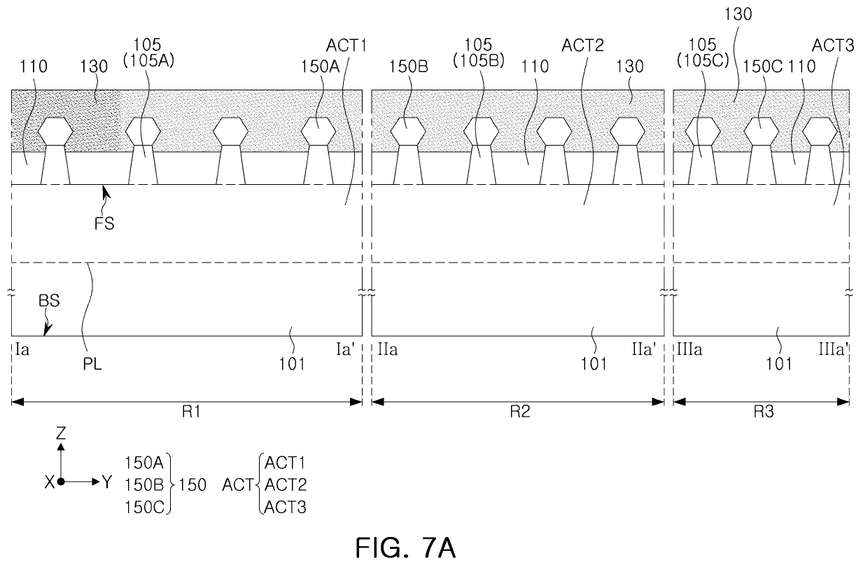

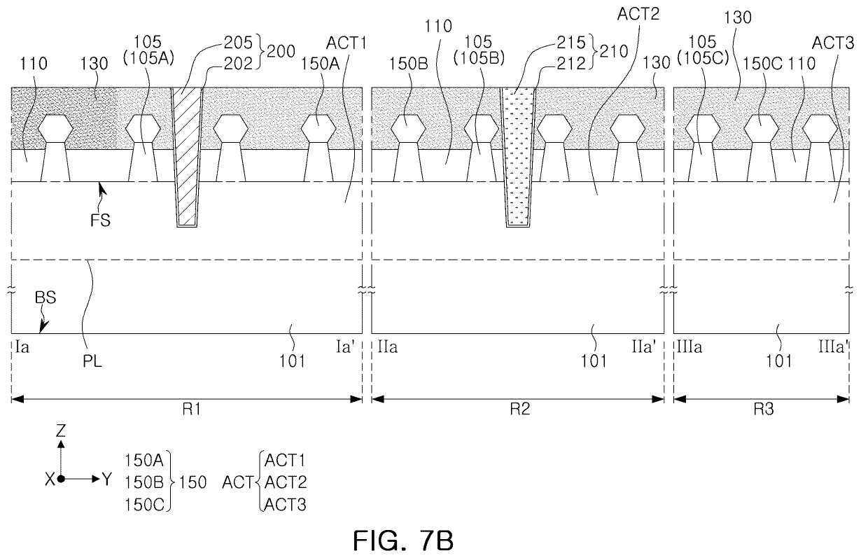

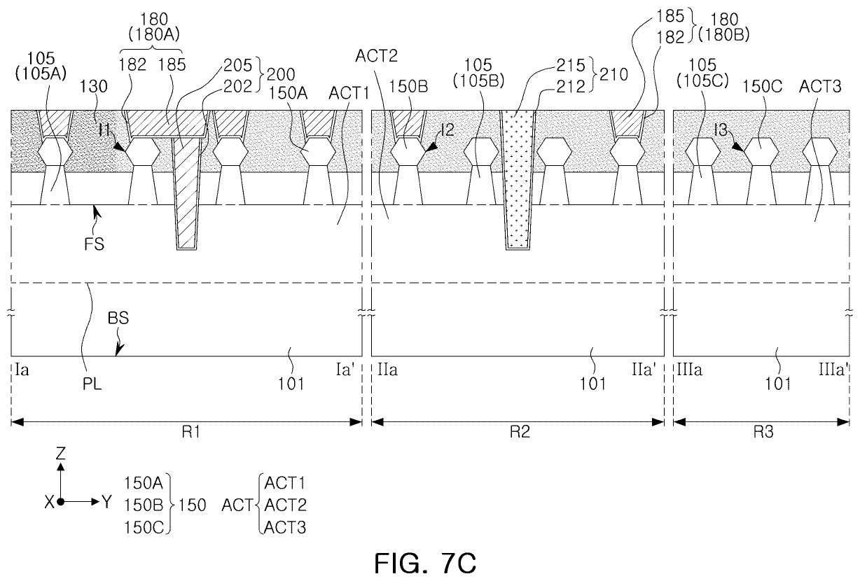

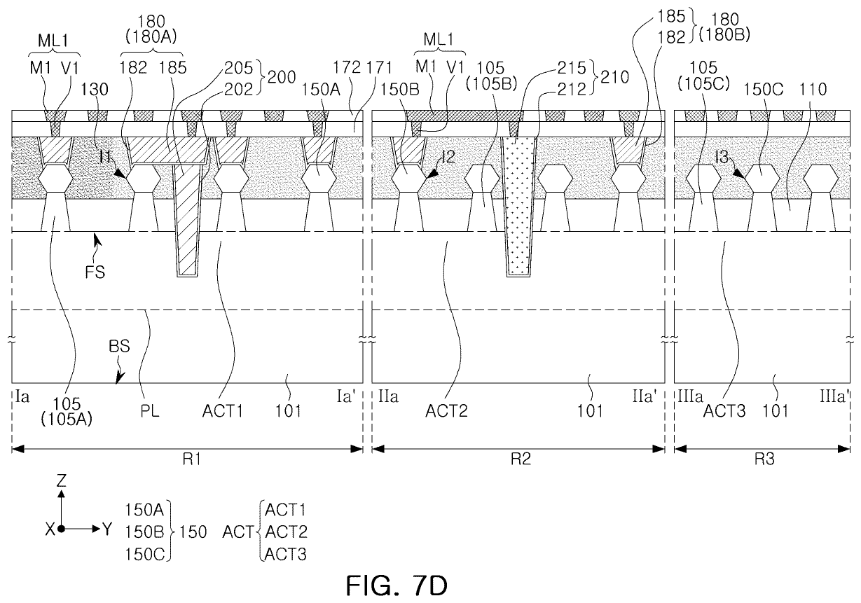

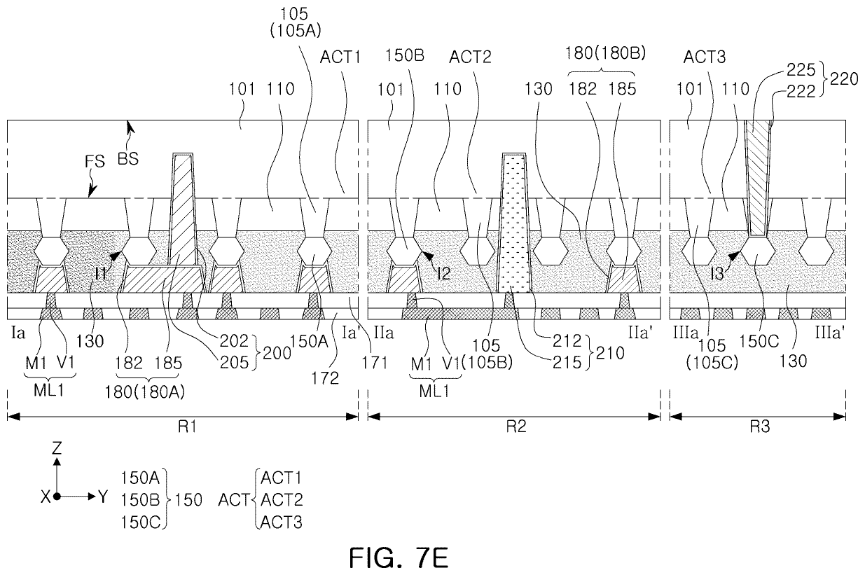

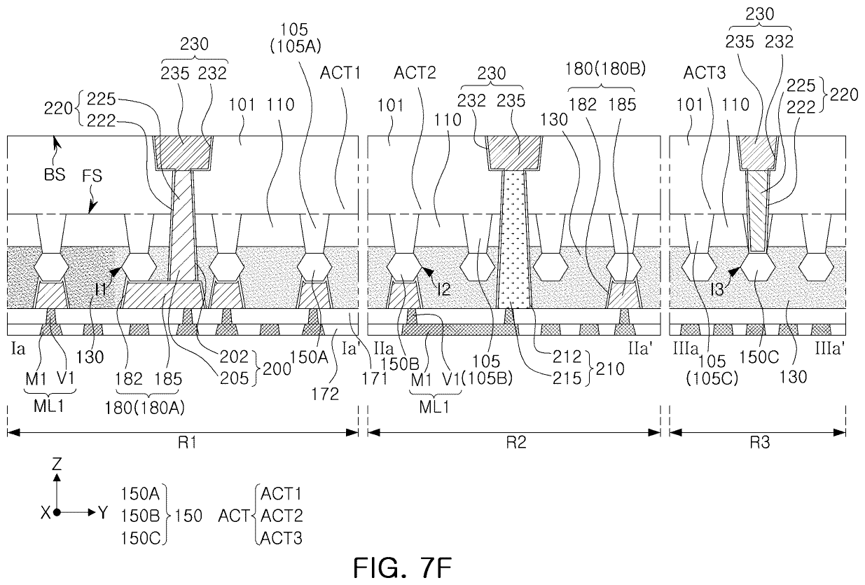

The lower interlayer insulating layer 270 may have an upper surface extending in an X-direction and a Y-direction. The lower interlayer insulating layer 270 may be a layer formed by removing and/or oxidizing a substrate 101 formed of a semiconductor material (see FIG. 7E) during a manufacturing process. For example, in the process of FIG. 7E, the substrate 101 may be removed and the lower interlayer insulating layer 270 may be formed. The lower interlayer insulating layer 270 may be formed of an insulating material, and may include, for example, oxide, nitride, or a combination thereof. In some example embodiments, the lower interlayer insulating layer 270 may include a plurality of insulating layers.

In the semiconductor device 100b, the first conductive through-structure 200 and the third conductive through-structure 220 may be disposed in each region on the lower interlayer insulating layer 270. According to an example embodiment, power may be supplied to first elements I1 and third elements I3 in different manners by the first conductive through-structure 200 and the third conductive through-structure 220. For example, in a first region R1, the first conductive through-structure 200 may serve as an electrical path for receiving power supply voltage from a backside interconnection structure ML2 and supplying the power supply voltage to the first elements I1 through a first contact structure 180A. In a third region R3, the third conductive through-structure 220 may serve as an electrical path for receiving power supply voltage from the backside interconnection structure ML2 and supplying the power supply voltage to the third elements I3. The first conductive through-structure 200 and the third conductive through-structure 220 may be connected to a power delivery structure 230 extending from a lower surface of the lower interlayer insulating layer 270. The third conductive through-structure 220 may pass through a portion of a third source/drain region 150C, such that a level of an upper end of the third conductive through-structure 220 may be higher than a level of a lower end of the third source/drain region 150C, but the present disclosure is not limited thereto. According to an example embodiment, a plurality of first active patterns 105A may be disposed at a first interval L1′ in the first region R1. In a second region R2, a plurality of second active patterns 105B may be disposed at a second interval L2′ substantially the same as the first interval L1′. For example, a pattern density of the first region R1 may be substantially the same as that of the third region R3, but the present disclosure is not limited thereto.

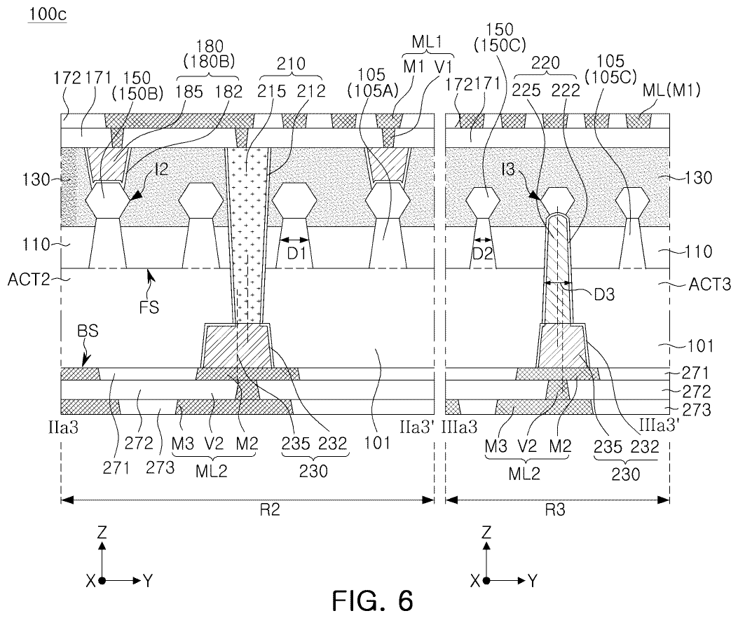

FIG. 6 are schematic cross-sectional views of a semiconductor device according to an example embodiment. FIG. 6 illustrates a cross-sectional view corresponding to a cross-section taken along IIa-IIa′ of FIG. 3B and a cross-sectional view corresponding to a cross-section taken along IIIa-IIIa′ of FIG. 3C as a cross-sectional view taken along IIa3-IIa3′ and a cross-sectional view taken along IIIa3-IIIa3′, respectively. In the following description, contents overlapping those described above will be omitted.

Unlike the semiconductor device 100 of FIGS. 1, 2A, 2B, 2C, 3A, 3B, and 3C, power supply voltage may be supplied to a semiconductor device 100c by a second conductive through-structure 210 and a third conductive through-structure 220 excluding a first conductive through-structure 200 on a substrate 101.

The second conductive through-structure 210 and a third conductive through-structure 220 may be disposed in each region on the substrate 101. According to an example embodiment, power may be supplied to second elements I2 and third elements I3 in different manners by the second conductive through-structure 210 and the third conductive through-structure 220. For example, in a second region R2 having a second pattern density, the second conductive through-structure 210 may serve as an electrical path for receiving power supply voltage from a backside interconnection structure ML2 and supplying the power supply voltage to the second elements I2 through a frontside interconnection structure ML1 and a second contact structure 180B. The second conductive through-structure 210 may be connected to a power delivery structure 230 extending from a back surface BS of the substrate 101. According to an example embodiment, a central axis of the second conductive through-structure 210 and a central axis of the power delivery structure 230 may be shifted.

According to an example embodiment, in a third region R3 having a third pattern density, the third conductive through-structure 220 may serve as an electrical path for receiving power supply voltage from a backside interconnection structure ML2 and supplying the power supply voltage to the third elements I3. The third conductive through-structure 220 may be connected to the power delivery structure 230 extending from the back surface BS of the substrate 101. The third source/drain region 150C may be electrically connected to the power delivery structure 230 through the third conductive through-structure 220 to receive power. According to an example embodiment, a central axis of the third conductive through-structure 220 and a central axis of the power delivery structure 230 may be shifted. An upper end of the third conductive through-structure 220 may have a rounded shape. The third conductive through-structure 220 may pass through a portion of the third source/drain region 150C, such that a level of an upper end of the third conductive through-structure 220 may be higher than a level of a lower end of the third source/drain region 150C, but the present disclosure is not limited thereto.

A width D1 of each of a plurality of second active patterns 105B in a Y-direction may be greater than a width D2 of each of a plurality of third active patterns 105C in the Y-direction. According to an example embodiment, a width D3 of the third conductive through-structure 220 in the Y-direction may be greater than the width D2 of each of the plurality of third active patterns 105C in the Y-direction.

FIGS. 7A, 7B, 7C, 7D, 7E and 7F are cross-sectional views illustrating sequential processes of a method of manufacturing a semiconductor device according to an example embodiment. FIGS. 7A, 7B, 7C, 7D, 7E and 7F illustrate regions corresponding to cross-sections of FIGS. 3A, 3B, and 3C taken along 1a-1a′, IIa-IIa′, and IIIa-IIIa′. Hereinafter, the terms such as “top,” “upper portion,” “upper surface,” “above,” “bottom,” “lower portion,” “lower surface,” “below,” and “side surface” may be understood as being referred to based on the drawings except for being denoted by reference numerals.

Referring to FIG. 7A, a gate-all-around type field effect transistor may be formed on an upper surface of a substrate. Specifically, the transistor may include an active region ACT, a plurality of channel layers NS stacked on the active region ACT to be spaced apart from each other, a gate structure GS crossing the active region ACT, and a source/drain region 150 disposed on the active region ACT on opposite sides of the gate structure GS to be connected to opposite side surfaces of the plurality of channel layers NS. An interlayer insulating layer 130, covering the source/drain region 150 and the gate structure GS, may be further formed.

Referring to FIG. 7B, a first conductive through-structure 200 and a second conductive through-structure 210 may be formed. The first conductive through-structure 200 and the second conductive through-structure 210, passing through a portion of the interlayer insulating layer 130, an device isolation layer 110, and a substrate 101, may be formed. After the first conductive through-structure 200 and the second conductive through-structure 210 respectively form a first insulating liner 202 and a second insulating liner 212, a remaining space may be formed by filling a first contact plug 205 and a second contact plug 215, but the present disclosure is not limited thereto.

Referring to FIG. 7C, a first contact structure 180A and a second contact structure 180B may be formed. In a first region R1, a contact hole, connected with at least a portion of first elements I1, may be formed. In a process of forming the contact hole, an upper portion of the first conductive through-structure 200 may be removed. After a barrier layer 182 and a plug conductive layer 185 are sequentially formed to fill the contact hole, a planarization process such as a CMP may be performed, such that an upper surface of a contact structure 180 and an upper surface of the interlayer insulating layer 130 may be substantially coplanar with each other. In addition, an upper surface of the first conductive through-structure 200 may be in contact with a lower surface of the first contact structure 180A.

In a second region R2, a contact hole may be formed in a position spaced apart from that of the second conductive through-structure 210. Subsequently, after a barrier layer 182 and a plug conductive layer 185 are sequentially formed to fill the contact hole, a planarization process such as a CMP may be performed, such that an upper surface of the contact structure 180 and an upper surface of the interlayer insulating layer 130 may be substantially coplanar with each other. In addition, an upper portion of the second conductive through-structure 210 may not be removed during a process of forming the contact hole, such that an upper surface of the second contact structure 180B and an upper surface of the second conductive through-structure 210 may be substantially coplanar with each other.

In a third region R3, the contact structure 180, having a structure similar to that of the first contact structure 180A or the second contact structure 180B, may not be formed, but the present disclosure is not limited thereto.

Referring to FIG. 7D, a frontside interconnection structure ML1 may be formed on a front surface FS of the substrate 101. A plurality of frontside interconnection lines M1 and a plurality of frontside interconnection vias V1 may be formed together using a dual-damascene process. In the first region R1, the plurality of frontside interconnection vias V1 may be formed on the first contact structure 180A. In the second region R2, the plurality of frontside interconnection vias V1 may be in contact with the second conductive through-structure 210. Although the plurality of frontside interconnection vias V1 are not illustrated in the third region R3, the plurality of frontside interconnection vias V1 may be selectively formed.

Referring to FIG. 7E, the substrate 101 may be turned over and a back grinding process may be performed on a back surface BS of the substrate 101. In FIG. 7E, for ease of understanding, it is illustrated that the structure of in FIG. 7D is bonded in the form of a mirror image. In order to reduce the thickness of the substrate 101, the back grinding process may be performed on upper and lower surfaces of the substrate 101. For example, the back grinding process may be performed up to a portion indicated with “PL.”

Subsequently, in the third region R3, the third conductive through-structure 220 may be formed to be in direct contact with a third source/drain region 150C. The third conductive through-structure 220 may be formed to extend from the back surface BS to the front surface FS of the substrate 101. The third conductive through-structure 220 may pass through the substrate 101 and the third active region ACT3 to be in contact with the third source/drain region 150C.

Referring to FIG. 7F, a power delivery structure 230 may be formed on the back surface BS of the substrate 101. First, a hole may be formed in the substrate 101. During a process of forming a hole H, the first and second insulating liners 202 and 212 of the first and second conductive through-structures 200 and 210 may be partially removed to expose the first and second contact plugs 205 and 215. In addition, an upper portion of the third conductive through-structure 220 may be partially removed.

Subsequently, a fourth insulating liner 232 may be formed on an internal surface of the hole, and a fourth contact plug 235 may be formed to fill the hole. The fourth insulating liner 232 may be conformally deposited on an upper surface of the substrate 101 in addition to the internal surface of the hole. For example, the present deposition process may be formed by an atomic layer deposition (ALD) process, a chemical vapor deposition (CVD) process, or a physical vapor deposition (PVD) process. Subsequently, a portion of the fourth insulating liner 232, positioned on a bottom surface of the hole, may be selectively removed to expose portions of upper surfaces of the first to third contact plugs 205, 215, and 225.

Subsequently, a conductive material may be deposited such that the fourth contact plug 235 is filled in the hole, and then a planarization process such as a CMP may be performed to remove a material positioned on the substrate 101 together. As a result, the power delivery structure 230, extending from the rear surface BS to the front surface FS of the substrate 101 to be connected to the first to third conductive through-structures 200, 210, and 220, may be formed.

Subsequently, referring to FIGS. 3A, 3B, and 3C together, the semiconductor device 100 illustrated in FIGS. 3A to 3C may be manufactured by forming a backside interconnection structure ML2 connected to the power delivery structure 230 in a subsequent process.

According to example embodiments of the present disclosure, two or more conductive through-structures, supplying power, may be disposed on a substrate in different manners, such that a semiconductor device may have an improved degree of integration and/or electrical properties.

While example embodiments have been illustrated and described above, it will be apparent to those skilled in the art that modifications and variations could be made without departing from the scope of the present disclosure as defined by the appended claims.

What is claimed is:

1. A semiconductor device comprising:
a substrate including a first active region and a second active region,
the first active region and the second active region extending in a first direction,
the first active region including a plurality of first active patterns spaced apart from each other by a first interval,
the second active region including a plurality of second active patterns spaced apart from each other by a second interval,
the second interval being different from the first interval;
an device isolation layer on the substrate, the device isolation layer surrounding the first active region and the second active region;
a gate structure on the substrate, the gate structure extending in a second direction, the second direction intersecting the first direction;
a first source/drain region on the first active region and a second source/drain region on the second active region, the first source/drain region and the second source/drain region on opposite sides of the gate structure, respectively;
an interlayer insulating layer on the device isolation layer, the interlayer insulating layer covering the gate structure, the first source/drain region, and the second source/drain region;
a first contact structure and a second contact structure passing through the interlayer insulating layer, the first contact structure and the second contact structure being connected to the first source/drain region and the second source/drain region, respectively;
a first conductive through-structure and a second conductive through-structure electrically connected to the first contact structure and the second contact structure, respectively, the first conductive through-structure and the second conductive through-structure passing through the substrate and the interlayer insulating layer;
a power delivery structure extending from a back surface of the substrate toward a front surface of the substrate, the power delivery structure in contact with a bottom surface of the first conductive through-structure and a bottom surface of the second conductive through-structure;
a frontside interconnection structure on the front surface of the substrate, the frontside interconnection structure including frontside interconnection patterns; and
a backside interconnection structure on the back surface of the substrate, the backside interconnection structure including backside interconnection patterns, wherein
the first conductive through-structure is in contact with a lower portion of the first contact structure,
the first conductive through-structure is electrically connected to the first source/drain region through the first contact structure, and
the second conductive through-structure is spaced apart from the second contact structure,
the second conductive through-structure is in contact with the frontside interconnection structure, and
the second conductive through-structure is electrically connected to the second source/drain region through the frontside interconnection structure.

2. The semiconductor device of claim 1, wherein
a level of an upper end of the first conductive through-structure is lower than a level of an upper end of each of the first contact structure and the second contact structure, and
a level of an upper end of the second conductive through-structure is a same level as the level of the upper end of the first contact structure and the level of the upper end of the second contact structure.

3. The semiconductor device of claim 1, wherein
a width of the first conductive through-structure in the second direction is greater than a width of the second conductive through-structure in the second direction.

4. The semiconductor device of claim 1, wherein
a level of a contact surface between the first conductive through-structure and the power delivery structure is lower than a level of a contact surface between the second conductive through-structure and the power delivery structure.

5. The semiconductor device of claim 1, wherein
each of the plurality of first active patterns has a first width,
each of the plurality of second active patterns has a second width, and
the second width is different from the first width.

6. The semiconductor device of claim 1, comprising:
a plurality of channel layers on the first active region and the second active region, the plurality of channel layers being spaced apart from each other in a vertical direction, the vertical direction being perpendicular to an upper surface of the substrate, wherein
the gate structure includes a gate electrode and a gate dielectric layer,
the gate structure extends in the second direction while surrounding each of the plurality of channel layers, and
the gate dielectric layer is between the plurality of channel layers and the gate electrode.

7. The semiconductor device of claim 1, further comprising:
a third source/drain region a third active region of the substrate; and
a third conductive through-structure extending from the back surface of the substrate toward the front surface of the substrate, wherein
the third active region includes a plurality of third active patterns spaced apart from each other by a third interval,
the third interval is less than the first interval and less than second interval,
the third source/drain region is on opposite sides of the gate structure,
the third conductive through-structure is connected to the third source/drain region and below the third source/drain region, and
the first interval is greater than the second interval.

8. The semiconductor device of claim 7, wherein
the first conductive through-structure and the second conductive through-structure respectively have widths gradually increasing from the back surface of the substrate toward the front surface of the substrate, and
the third conductive through-structure has a width gradually decreasing from the back surface of the substrate toward the front surface of the substrate.

9. The semiconductor device of claim 7, wherein
a level of an upper end of the third conductive through-structure is higher than a level of a lower end of the third source/drain region.

10. The semiconductor device of claim 7, wherein
a level of an upper end of the first conductive through-structure is lower than a level of an upper end of the second conductive through-structure, and
the level of the upper end of the first conductive through-structure is higher than a level of an upper end of the third conductive through-structure.

11. A semiconductor device comprising:
a substrate having a first region having a first pattern density and a second region having a second pattern density;
first elements on the substrate in the first region;
a first conductive through-structure passing through the substrate, the first conductive through-structure electrically connected to the first elements;
second elements on the substrate in the second region;
a second conductive through-structure passing through the substrate, the second conductive through-structure electrically connected to the second elements;
a contact structure connected to at least one of each of the first elements in the first region or each of the second elements in the second region;
a power delivery structure extending from a back surface of the substrate toward a front surface of the substrate, the power delivery structure in contact with a bottom surface of the first conductive through-structure and a bottom surface of the second conductive through-structure;
a frontside interconnection structure electrically connected to at least one of the first elements or the second elements on the front surface of the substrate, the frontside interconnection structure including frontside interconnection patterns in contact with an upper surface of the contact structure; and
a backside interconnection structure including backside interconnection patterns adjacent to the back surface of the substrate, the back surface of the substrate being opposite the front surface of the substrate, wherein
a level of an upper end of the first conductive through-structure is different from a level of an upper end of the second conductive through-structure, and
at least one of the first conductive through-structure or the second conductive through-structure extends from the front surface of the substrate toward the back surface of the substrate and is spaced apart from the contact structure.

12. The semiconductor device of claim 11, wherein
the first conductive through-structure is spaced apart from the first elements and the first conductive through-structure is electrically connected to the first elements through the contact structure, and
the second conductive through-structure is spaced apart from the second elements and the second conductive through-structure is electrically connected to the second elements through the frontside interconnection structure.

13. The semiconductor device of claim 11, wherein the second pattern density is higher than the first pattern density.

14. The semiconductor device of claim 13, further comprising:
a third conductive through-structure passing through the substrate; and
third elements on a third region of the substrate, wherein
the third region has a third pattern density,
the third pattern density is higher than the second pattern density, and
the third conductive through-structure is in contact with the third elements.

15. The semiconductor device of claim 13, wherein
the first conductive through-structure is in contact with a lower portion of the contact structure, and
the second conductive through-structure and the third conductive through-structure are spaced apart from the contact structure.

16. The semiconductor device of claim 13, wherein
the level of the upper end of the second conductive through-structure is a same level as a level of an upper end of the contact structure, and
the level of the upper end of the second conductive through-structure is higher than the level of the upper end of the first conductive through-structure, and
the level of the upper end of the first conductive through-structure is higher than a level of an upper end of the third conductive through-structure.

17. The semiconductor device of claim 13, wherein
the first conductive through-structure and the second conductive through-structure extend from the front surface of the substrate toward the back surface of the substrate, and
the third conductive through-structure extends from the back surface of the substrate toward the front surface of the substrate.

18. A semiconductor device comprising:
a substrate including a first active region, a second active region, and a third active region,
the first active region, the second active region, and the third active region extending in a first direction,
the first active region including a plurality of first active patterns spaced apart from each other by a first interval,
the second active region including a plurality of second active patterns spaced apart from each other by a second interval, the second interval being different from the first interval,
the third active region including a plurality of third active patterns spaced apart from each other by a third interval, the third interval being less than the second interval;
an device isolation layer surrounding the first active region, the second active, and the third active region on the substrate;
a gate structure extending in a second direction, the second direction intersecting the first direction;
a first source/drain region on the first active region, a second source/drain region on the second active region, and a third source/drain region on the third active region,
the first source/drain region, the second source/drain region, and the third drain region on opposite sides of the gate structure, respectively;
an interlayer insulating layer on the device isolation layer, the interlayer insulating layer covering the gate structure, the first source/drain region, the second source/drain region, and the third source/drain region;
a first contact structure and a second contact structure passing through the interlayer insulating layer, the first contact structure and the second contact structure being connected to the first source/drain region and the second source/drain region, respectively;
a first conductive through-structure and a second conductive through-structure electrically connected to the first contact structure and the second contact structure, respectively,
the first conductive through-structure and the second conductive through-structure passing through the substrate and the interlayer insulating layer;
a third conductive through-structure extending from a back surface of the substrate toward a front surface of the substrate, the third conductive through-structure connected to the third source/drain region and below the third source/drain region; and
power delivery structures extending from the back surface of the substrate toward the front surface of the substrate, the power delivery structures in contact with a bottom surface of the first conductive through-structure, a bottom surface of the second conductive through-structure, and a bottom surface of the third conductive through-structure, respectively, wherein
a level of an upper end of the second conductive through-structure is higher than a level of an upper end of the first conductive through-structure, and
the level of the upper end of the first conductive through-structure is higher than a level of an upper end of the third conductive through-structure.

19. The semiconductor device of claim 18, further comprising:
a frontside interconnection structure on the front surface of the substrate, the frontside interconnection structure including frontside interconnection patterns; and
a backside interconnection structure on the back surface of the substrate, the backside interconnection structure including backside interconnection patterns, wherein
the first conductive through-structure is in contact with a lower portion of the first contact structure,
the first conductive through-structure is electrically connected to the first source/drain region through the first contact structure, and
the second conductive through-structure is spaced apart from the second contact structure,
the second conductive through-structure is in contact with the frontside interconnection structure, and
the second conductive through-structure is electrically connected to the second source/drain region through the frontside interconnection structure.

20. The semiconductor device of claim 18, wherein
each of the plurality of first active patterns has a first width,
each of the plurality of second active patterns has a second width,
the second width is less than the first width,
each of the plurality of third active patterns has a third width, and
the third width is less than the second width.
